(19) United States
(12) Patent Application Publication
(10) Pub. No.: US 2006/0220214 A1
(43) Pub. Date: Oct. 5, 2006

(54) Semiconductor device and manufacturing method thereof

(76) Inventor: Mamoru Ando, Gunma (JP)

Correspondence Address: FISH & RICHARDSON P.C., P.O. BOX 1022, MINNEAPOLIS, MN, 55440-1022, US

(21) Appl. No.: 11/378,914

(22) Filed: Mar. 17, 2006

(30) Foreign Application Priority Data
Mar. 29, 2005 (JP) P2005-093695

(51) Int. Cl. H01L 23/48

(52) U.S. Cl. 257/690; 257/E23.011

(57) ABSTRACT

A semiconductor device of the present invention includes: a substrate having a first region and second regions; dicing grooves which separate the first region from the second regions; step parts which are provided on surfaces of the first region and the second regions of the substrate adjacent to the dicing grooves, and expose the substrate; and a resin layer which integrally supports the substrate on the surfaces of the first region and the second regions of the substrate including the step parts, thereby, adhesion of the resin layer to the step parts is improved.

Priority is claimed to Japanese Patent Application Number JP2005-093695 filed on Mar. 29, 2005, the disclosure of which is incorporated herein by reference in its entirety.

### BACKGROUND OF THE INVENTION

1. Field of the Invention

The present invention relates to a method for manufacturing a semiconductor device, and more particularly relates to a method for manufacturing a semiconductor device according to a wafer level chip size package.

2. Description of the Related Art

A semiconductor device having a transistor element formed on a silicon substrate generally has a configuration as shown in FIG. 17. Reference numeral 1 is a silicon substrate, reference numeral 2 is an island such as a heat sink, on which the silicon substrate 1 is mounted, reference numeral 3 is a lead terminal, and reference numeral 4 is a resin for sealing.

As shown in FIG. 17, the silicon substrate 1 having a transistor element formed thereon is fixed to and mounted on the island 2 such as a copper base heat sink by use of a solder material 5 such as a solder. Moreover, a bonding wire is used to electrically connect a base electrode and an emitter electrode of the transistor element to the lead terminal 3 disposed on a periphery of the silicon substrate 1. A lead terminal connected to a collector electrode is integrally formed with the island and is electrically connected by mounting the silicon substrate on the island. Thereafter, transfer molding is performed by use of the thermosetting resin 4 such as an epoxy resin.

A resin-molded semiconductor device is usually mounted on a mounting substrate such as a glass epoxy substrate and electrically connected to another semiconductor devices and circuit elements which are mounted on the mounting substrate. Accordingly, the semiconductor device is treated as one component for performing predetermined circuit operations.

Meanwhile, considering a ratio of a semiconductor chip area actually having functions to a mounting area as an effective area ratio, it is understood that the resin-molded semiconductor device has a very low effective area ratio. The low effective area ratio causes most of the mounting area to be a dead space which is not directly related to a semiconductor chip having functions. Thus, the low effective area ratio interferes with high-density miniaturization of a mounting substrate 30.

Particularly, the problem described above is obvious in a semiconductor device having a small package size. For example, as shown in FIG. 18, a maximum size of a semiconductor chip mounted on SC-75A shape according to EIAJ standard is 0.40 mm×0.40 mm. When this semiconductor chip is resin-molded as shown in FIG. 18, the size of the entire semiconductor device is set to 1.6 mm×1.6 mm. A chip area of the semiconductor device is 0.16 mm², and a mounting area for mounting the semiconductor device is 2.56 mm² considering the mounting area to be approximately the same as an area of the semiconductor device. Thus, an effective area ratio of the semiconductor device is about 6.25%. Consequently, most of the mounting area is a dead space which is not directly related to the semiconductor chip area having functions.

As to a mounting substrate used in recent electronic devices, for example, a personal computer, a portable information processing device, a video camera, a portable telephone, a digital camera, a liquid crystal TV and the like, along with miniaturization of a main body of the electronic device, the mounting substrate used therein also tends to be densified and miniaturized.

However, in the semiconductor device described above, the large dead space interferes with miniaturization.

Meanwhile, the inventors of the present application have proposed Japanese Patent Application Publication No. Hei 10 (1998)-12651 as a conventional technology for improving an effective area ratio. As shown in FIG. 19, the conventional technology includes: a semiconductor substrate 60; an active element formation region 61 in which an active element is formed; an external connection electrode 62 for external connection, which is one of electrodes of the active element formed in the active element formation region 61; other external connection electrodes 63 and 64 which are electrically isolated from the active element formation region 61 and set a part of the substrate 60 to be an external electrode of the other electrode of the active element; and connection 65 connecting the other electrode of the active element to the other external connection electrodes 63 and 64. In a surface of the active element formation region 61, a P+ type base region 71, an N+ type emitter region 72, and an N+ type guard ring diffusion region 73 are provided. An insulating film 74 covers the surface, and a base electrode 75, an emitter electrode 76 and a connection electrode 77 are provided. A resin layer 78 is provided on the insulating film 74 and integrally supports the active element formation region 61 and the other external connection electrodes 63 and 64. This technology is described in Japanese Patent Application Publication No. Hei 10 (1998)-12651.

However, in the above-described semiconductor device of a chip size package, due to a structure in which the semiconductor substrate 60 is divided by slit holes 80, the semiconductor substrate 60 is required to be supported and fixed on the same plane by the resin layer 78. However, since the resin layer 78 is attached to the insulating film 74 and has an even thickness, there is a significant problem from a practical standpoint that sufficient strength has not yet been obtained.

Moreover, since the slit holes 80 are formed from a rear surface of the semiconductor substrate 60, there is no mark to be a reference. Thus, there also remains a problem that positioning in formation of slit holes is difficult.

### SUMMARY OF THE INVENTION

The present invention was made in consideration for the foregoing problems. The present invention provides a semiconductor device of a wafer level chip size package, which is most suitable for practical application, and a manufacturing method thereof.

The present invention provides a semiconductor device that includes a substrate having a first and a second region, a circuit element provided in the first region and a plurality of electrodes connected to the circuit element, an external connection electrode having a metallic through electrode buried in the second region, a dicing groove which divides the substrate into the first region and the second region, connections electrically connecting the electrodes to the external connection electrode, step parts which are provided on surfaces of the first and second regions of the substrate adjacent to the dicing groove, and expose a part of the substrate, and a resin layer which is provided on the surface of the substrate including the step parts so as to support integrally the first and second regions of the substrate.

The present invention provides a method of manufacturing a semiconductor device. The method includes forming an epitaxial layer in an upper surface of a substrate having, on its principal surface, a first region for forming a circuit element and a plurality of second regions disposed so as to be equally spaced apart from the first region in a periphery of the first region, forming the circuit element on the epitaxial layer in the first region, forming step parts at least in regions where dicing grooves are to be formed in the epitaxial layer, reducing a thickness of the substrate from a rear surface thereof, forming via holes that reach a surface of the substrate from the rear surface thereof in the second regions, and forming through electrodes made of metal in the via holes, forming connection electrically connecting electrodes of the circuit element to the through electrodes on the principal surface of the substrate, improving adhesion to the step parts by forming a resin layer which integrally supports the first region and the second regions on a surface of the epitaxial layer, and forming the dicing grooves that reach the resin layer in the substrate on boundaries between the first region and the second regions based on the through electrodes from the rear surface of the substrate, electrically separating the substrate in the first region from the substrate in the second regions, and forming external connection electrodes made of the substrate in the second regions.

The present invention also provides a method for manufacturing a semiconductor device. The method includes preparing a substrate having, on its principal surface, a first region for forming a circuit element and a plurality of second regions disposed so as to be equally spaced apart from the first region in a periphery of the first region by providing an epitaxial layer on a semiconductor substrate, forming the circuit element on the epitaxial layer in the first region, forming via holes that reach the semiconductor substrate from surfaces in the second regions of the substrate, and forming through electrodes made of metal in the via holes, forming step parts at least in regions where dicing grooves are to be formed in the epitaxial layer, forming connection electrically connecting electrodes of the circuit element to the through electrodes on a surface of the epitaxial layer, improving adhesion to the step parts by forming a resin layer which integrally supports the first region and the second regions on the surface of the epitaxial layer, reducing a thickness of the semiconductor substrate by grinding the semiconductor substrate from its rear surface, and exposing the through electrodes from rear surfaces of the second regions, and forming the dicing grooves that reach the resin layer in the substrate on boundaries between the first region and the second regions based on the through electrodes from a rear surface of the substrate, electrically separating the substrate in the first region from the substrate in the second regions, and forming external connection electrodes made of the substrate in the second regions.

### BRIEF DESCRIPTION OF THE DRAWINGS

FIG. 1 is a cross-sectional view showing a semiconductor device according to an embodiment of the present invention.

FIG. 2 is a cross-sectional view showing a method for manufacturing a semiconductor device according to an embodiment of the present invention.

FIG. 3 is a cross-sectional view showing the method for manufacturing a semiconductor device according to the embodiment of the present invention.

FIG. 4 is a cross-sectional view showing the method for manufacturing a semiconductor device according to the embodiment of the present invention.

FIG. 5 is a cross-sectional view showing the method for manufacturing a semiconductor device according to the embodiment of the present invention.

FIG. 6 is a cross-sectional view showing the method for manufacturing a semiconductor device according to the embodiment of the present invention.

FIG. 7 is a cross-sectional view showing the method for manufacturing a semiconductor device according to the embodiment of the present invention.

FIG. 8 is a cross-sectional view showing the method for manufacturing a semiconductor device according to the embodiment of the present invention.

FIG. 9 is a plan view showing the method for manufacturing a semiconductor device according to the embodiment of the present invention.

FIG. 10 is a cross-sectional view showing a method for manufacturing a semiconductor device according to another embodiment of the present invention.

FIG. 11 is a cross-sectional view showing the method for manufacturing a semiconductor device according to the other embodiment of the present invention.

FIG. 12 is a cross-sectional view showing the method for manufacturing a semiconductor device according to the other embodiment of the present invention.

FIG. 13 is a cross-sectional view showing the method for manufacturing a semiconductor device according to the other embodiment of the present invention.

FIG. 14 is a cross-sectional view showing the method for manufacturing a semiconductor device according to the other embodiment of the present invention.

FIG. 15 is a cross-sectional view showing the method for manufacturing a semiconductor device according to the other embodiment of the present invention.

FIG. 16 is a cross-sectional view showing the method for manufacturing a semiconductor device according to the other embodiment of the present invention.

FIG. 17 is a cross-sectional view showing a structure of a conventional semiconductor device.

FIG. 18 is a plan view showing a structure of a conventional semiconductor device.

FIG. 19 is a cross-sectional view showing a structure of a conventional semiconductor device.

### DESCRIPTION OF THE EMBODIMENTS

With reference to the drawings, embodiments of the present invention will be described below.

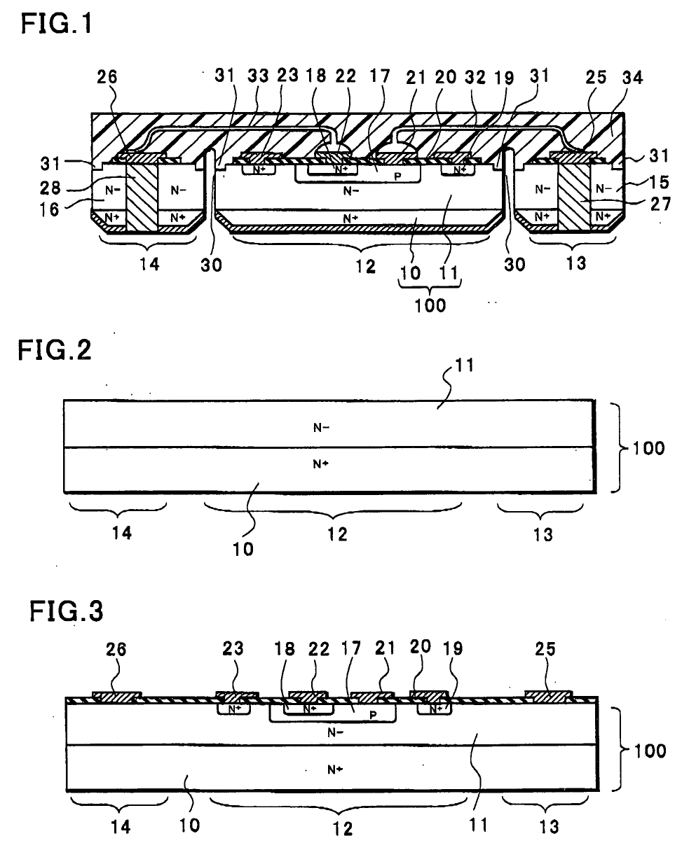

FIG. 1 is a cross-sectional view showing a semiconductor device according to an embodiment of the present invention. FIGS. 2 to 8 are cross-sectional views showing a method of manufacturing a semiconductor device according to a first embodiment of the present invention. FIG. 9 is a plan view showing a relationship in arrangement of electrodes in the semiconductor device according to the embodiment of the present invention.

As shown in FIG. 1, a substrate 100 is obtained by providing an N− type epitaxial layer 11 on an N+ type semiconductor substrate 10. The N+ type semiconductor substrate 10 is an N+ type single crystal silicon substrate. On the substrate 10, an N− type epitaxial layer 11 is formed by use of an epitaxial growth technology. A first region 12 in the center of the substrate 100 is set to be an active element formation region where an active circuit element (hereinafter circuit element) such as a power MOSFET and a transistor is formed. Second regions 13 and 14 on both sides of the first region 12 are set to be external connection electrode regions 15 and 16 to which electrodes of the circuit element are connected.

If the circuit element is a transistor, the epitaxial layer 11 comes to be a collector region, and a P type base region 17, an N+ type emitter region 18 and an N+ type guard ring region 19 are formed in a surface of the epitaxial layer 11. A surface of the circuit element is covered with an oxide film 20. Through respective contact holes, a base electrode 21, an emitter electrode 22 and a guard ring 23 are formed by sputtering aluminum.

On surfaces of the second regions 13 and 14, connection electrodes 25 and 26 are similarly formed, which perform connection to the circuit element. Moreover, through electrodes 27 and 28 are formed, which penetrate the second regions 13 and 14 from the surfaces to rear surfaces thereof. The through electrodes 27 and 28 are made of metal such as copper and are exposed on the rear surfaces of the second regions 13 and 14. Therefore, external connection electrodes are actually formed of the connection electrodes 25 and 26 on the surfaces of the second region 13 and the through electrodes 27 and 28. Since all the electrodes are made of metal, a leading-out resistance value can be lowered.

Dicing grooves 30 electrically and mechanically separate the first region 12 from the second regions 13 and 14, and are formed by cutting the substrate 100.

In this embodiment, step parts 31 are provided so as to correspond to the dicing grooves 30. In the step parts 31, the epitaxial layer 11 on the semiconductor substrate 10 in peripheries of the first region 12 and the second regions 13 and 14 are etched and exposed. The step parts 31 are provided so as to be adjacent to the dicing grooves 30. Furthermore, the step parts 31 are similarly provided the outside of the second regions 13 and 14. All the step parts 31 are provided for the purpose of improving adhesion to a resin layer 34.

The electrodes of the circuit element, in other words, the base electrode 21 and the emitter electrode 22 are connected to the connection electrodes 25 and 26 of the external connection electrodes by bonding with thin metal wires 32 and 33. As connections, a glass epoxy substrate having wiring previously formed thereon, a flexible substrate, a silicon substrate or the like may be used besides the above.

The surface of the substrate 100 is integrally covered with a resin layer 34. The resin layer 34 integrally supports the first region 12 and the second regions 13 and 14 of the substrate 100, which are separated by the dicing grooves 30, so as to hold the same plane. Moreover, the resin layer 34 also protects the thin metal wires 32 and 33.

In the embodiment of the present invention, the resin layer 34 improves adhesion by coming into direct contact with the epitaxial layer 11 on the semiconductor substrate 10 in the step parts 31. As the resin layer 34, a polyimide resin is preferable, and a combination with a silicon resin or an epoxy resin may be used.

In the structure of the embodiment of the present invention, the step parts 31, the surface of the epitaxial layer 11, the oxide film 20 and the respective electrodes of the circuit element, the connection electrodes 25 and 26 form stair-like steps. Accordingly, an area of adhesion to the resin layer 34 can be increased. Thus, the adhesion to the resin layer 34 can be improved. Particularly, the resin layer 34 can be formed to have the largest thickness in the portions where the dicing grooves 30 are formed. Thus, the resin layer 34 sufficiently withstands a stress applied when the dicing grooves 30 are formed. Moreover, for moisture entering through the dicing grooves 30, since enough paths can be gained at the stair-like steps, moisture-absorption characteristics can also be improved. Furthermore, the step parts 31 provided the outside of the second regions 13 and 14 similarly lead to improvement in the moisture-absorption characteristics.

(Method of Manufacturing Semiconductor Device According to First Embodiment of the Present Invention)

With reference to FIGS. 2 to 9, description will be given of a method of manufacturing a semiconductor device according to the first embodiment of the present invention.

As shown in FIG. 2, an epitaxial layer 11 is formed in an upper surface of a substrate 100 having, on its principal surface, a first region 12 for forming a circuit element and a plurality of second regions 13 and 14 disposed so as to be equally spaced apart from the first region 12 in a periphery of the first region 12.

First, as shown in FIG. 2, on an N+ type semiconductor substrate 10 made of an N+ type single crystal silicon, the N− type epitaxial layer 11 is formed by use of an epitaxial growth technology, thus preparing a substrate 100. The substrate 100 is divided into the first region 12, in which an active circuit element (hereafter circuit element) such as a power MOSFET and a transistor is formed, and the second regions 13 and 14, in which external connection electrodes are formed.

Next, as shown in FIG. 3, the circuit element is formed on the epitaxial layer 11 in the first region 12, and electrodes to be used for connecting the circuit element are formed on a surface of the epitaxial layer 11 in the first region 12.

After an insulating film 20 such as a Si oxide film, which is formed by thermal oxidation or CVD method, is formed on the N− type epitaxial layer 11 on the semiconductor substrate 10, an opening is formed in a part of the insulating film 20 to expose the N− type epitaxial layer 11. After P-type impurities such as boron (B) are selectively implanted into the N− type epitaxial layer 11 in the exposed region, thermal diffusion is performed. Thus, an island-shaped base region 17 is formed on the N− type epitaxial layer 11 in the first region 12.

After the base region 17 is formed, the insulating film 20 is formed again on the first region 12. An opening is formed in the insulating film 20 in a part of the base region 17, and the base region 17 is partially exposed. N-type impurities such as phosphorus (P) and antimony (Sb) are selectively implanted into the exposed base region 17. Thereafter thermal diffusion is performed. Thus, an emitter region 18 of a transistor is formed. In this embodiment, simultaneously with formation of the emitter region 18, a ring-shaped N+ type guard ring region 19 which surrounds the base region 17 is formed.

On the surface of the substrate 100, the insulating film 20 such as a silicon oxide film and a silicon nitride film is formed. Thereafter, a base contact hole for exposing a surface of the base region 17 and an emitter contact hole for exposing a surface of the emitter region 18 are formed by etching. In this embodiment, since the guard ring region 19 is formed, a guard ring contact hole for exposing a surface of the guard ring region 19 is simultaneously formed. Moreover, the insulating film 20 described above is also formed on the second regions 13 and 14 serving as the external connection electrodes. Therefore, external connection contact holes for exposing surfaces of formation regions of through electrodes to be formed are simultaneously formed in the etching step described above.

Thereafter, on the base region 17, the emitter region 18, formation regions of through electrodes to be formed and the guard ring region 19, all of which are exposed by the base contact hole, the emitter contact hole, the external connection contact holes and the guard ring contact hole, a metal material such as aluminum is selectively deposited. Thus, a base electrode 21, an emitter electrode 22, connection electrodes 25 and 26, and a guard ring 23 are selectively formed.

The first region 12 and the second regions 13 and 14 can be formed in arbitrary regions of the substrate 100. However, in this embodiment, as shown in FIG. 9, the first region 12 is formed in a center portion of the substrate 100 and the second regions 13 and 14 to be the external connection electrodes are arranged so as to form a triangular shape with the first region 12.

Through the steps described above, the substrate 100 is formed, on which an NPN transistor is provided as shown in FIG. 3.

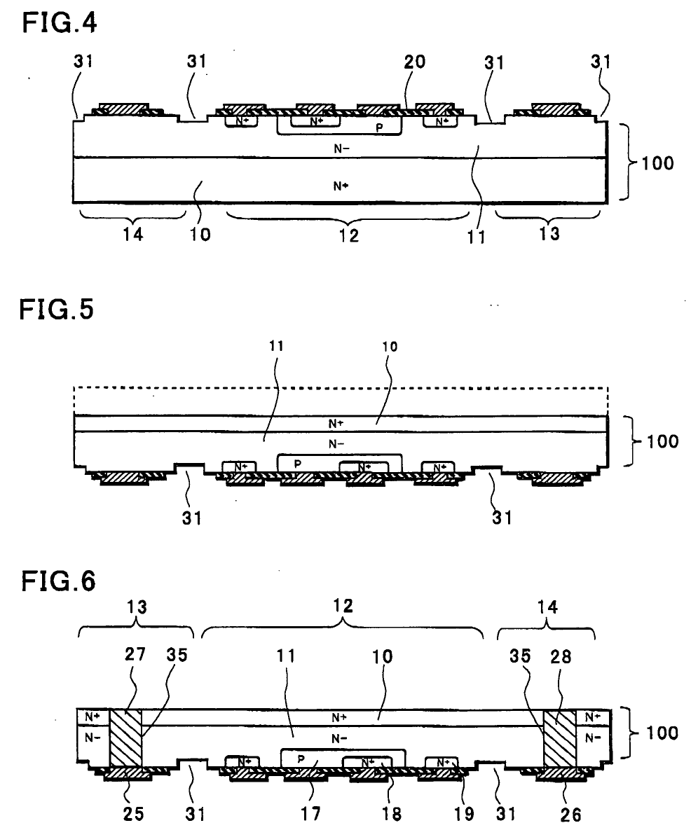

Furthermore, as shown in FIG. 4, step parts 31 are formed by etching at least in regions of the epitaxial layer 11 where dicing grooves (30) are to be formed.

In this step, the step parts 31 are formed by removing the insulating film 20 on the epitaxial layer 11 in regions on boundaries between the first region 12 and the second regions 13 and 14 and by etching the surface of the epitaxial layer 11. In this event, the step parts 31 may be simultaneously formed in the epitaxial layer 11 in the outside portions of the second regions 13 and 14. By forming the step parts 31, the periphery of the first region 12 and the peripheries of the second regions 13 and 14 are exposed from the insulating film 20. Furthermore, the step parts 31, the surface of the epitaxial layer 11, the oxide film 20 and the respective electrodes of the circuit element, the connection electrodes 25 and 26.

form stair-like steps. Accordingly, an area of adhesion to a resin layer to be formed later can be increased. Thus, the area of adhesion to the resin layer can be made larger.

Furthermore, as shown in FIGS. 5 and 6, a thickness of the semiconductor substrate 10 is reduced by grinding the semiconductor substrate 10 from a rear surface thereof, and via holes 35 that reach the surface of the substrate 100 from the rear surface thereof are formed in the second regions 13 and 14. Moreover, through electrodes 27 and 28 made of metal are formed in the via holes 35.

The surface of the substrate 100 is attached to a wafer support by use of wax and the like, and the substrate 100 is back-grind from its rear surface to remove an unnecessary portion thereof. Accordingly, the thickness of the semiconductor substrate 10 is reduced to about 400 μm to about 100 μm. Subsequently, the substrate 100 is transferred to an etching apparatus to form the via holes 35 in the second regions 13 and 14.

The substrate 100 is dry-etched from its rear surface by using a resist as a mask. Thus, the via holes 35 are formed, each of which has a width of about 70 μm and a length of about 100 μm. As etching gas used in dry etching, gas containing at least SF₇, O₂ or C₄F₈ is used. The via holes 35 are formed so as to reach the connection electrodes 25 and 26 from the rear surface of the substrate 100, and ends of the via holes 35 are detected by the connection electrodes 25 and 26. As a specific shape of the via holes 35, a cylindrical shape or a rectangular columnar shape may be used. Furthermore, the via holes 35 can also be formed by wet etching or by using a laser.

Next, the through electrodes 27 and 28 are formed so as to cover insides of the via holes 35 and part of the rear surface of the semiconductor substrate 10. The through electrodes 27 and 28 can be formed by plating or sputtering.

In the case where the through electrodes 27 and 28 are formed by plating, first, a seed layer (not shown), which is made of Cu and has a thickness of about several hundred nm, is formed on inner walls of the via holes 35 and on the entire rear surface of the semiconductor substrate 10. Next, electrolytic plating is performed by use of the seed layer as an electrode. Thus, on the inner walls of the via holes 35 and on the rear surface of the semiconductor substrate 10, the through electrodes 27 and 28 are formed, each of which has a thickness of about several μm and is made of Cu. Consequently, the through electrodes 27 and 28 are formed, which are electrically connected to the connection electrodes 25 and 26 through the via holes 35.

Although, here, the via holes 35 are completely filled with Cu formed by plating, the filling may be incomplete. Specifically, cavities may be provided in the via holes 35.

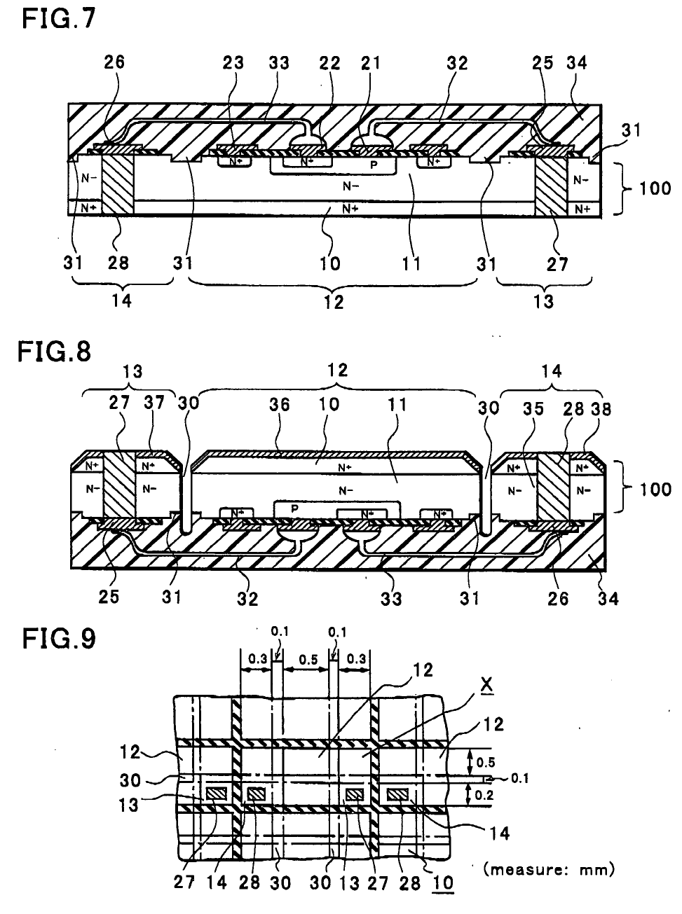

Furthermore, as shown in FIG. 7, on the principal surface, connection electrically connecting the electrodes of the circuit element to the external connection electrodes is formed. Thereafter, a resin layer 34, which integrally supports the first region 12 and the second regions 13 and 14, is formed on the surface of the epitaxial layer 11. Thus, the resin layer 34 adheres to the step parts 31.

The substrate 100 having the through electrodes 27 and 28 formed therein is detached from the wafer support and is attached again to the wafer support while exposing the surface thereof. Thereafter, the connection electrodes 25 and 26 corresponding to the base electrode 21 and the emitter electrode 22 are connected thereto by bonding with thin metal wires 32 and 33. Note that, instead of the thin metal wires 32 and 33, it is also possible to use a wiring substrate obtained by forming wiring in a substrate such as a glass epoxy substrate, a ceramic substrate, an insulated metal substrate, a phenol substrate and a silicon substrate. Here, since the step parts 31 are formed, it is possible to prevent the thin metal wires 32 and 33 from hanging and coming into contact with corner portions of the first region 12 or the second regions 13 and 14.

The resin layer 34 is formed so as to insulate the connection 32 and 33 connecting the base electrode 17 and the emitter electrode 18 of the transistor to the connection electrodes 25 and 26 as described above from the substrate 100. Moreover, the resin layer 34 is formed so as to integrally support the first region 12 and the second regions 13 and 14 when the first region 12 is mechanically separated from the second regions 13 and 14. As the resin layer 34, one including adhesive properties and insulating properties may be used, and, for example, a polyimide resin is preferable.

On the surface of the substrate 100, a polyimide resin having a film thickness of 2 μm to 50 μm is applied by use of a spinner, for example. After burning for a predetermined period of time, the resin layer 34 having its surface polished and flattened is formed.

Furthermore, as shown in FIG. 8, based on the through electrodes 27 and 28, dicing grooves 30 that reach the resin layer 34 are formed in the semiconductor substrate 10 and the epitaxial layer 11 on boundaries between the first region 12 and the second regions 13 and 14 from the rear surface of the semiconductor substrate 10. Accordingly, the substrate 100 in the first region 12 and the substrate 100 in the second regions 13 and 14 are mechanically separated from each other. Thus, external connection electrodes made of the substrate 100 in the second regions 13 and 14 are formed.

The dicing grooves 30 are formed so as to reach the resin layer 34 from the rear surface of the semiconductor substrate 10, and are formed by use of a mechanical method using a dicing apparatus.

The reason why the dicing grooves 30 are formed by use of the dicing apparatus is because dicing can be realized for a short period of time unlike etching, dicing width and depth can be accurately controlled, and the dicing apparatus is an existing equipment so that it is not required to purchase a new equipment. The dicing width is set according to a width of a dicing blade, and the dicing depth varies depending on dicing apparatus manufacturers. In the current technology, an error in accuracy of the dicing depth is about 2 μm to 5 μm. Thus, without cutting the connection 32 and 33, the first region 12 and the second regions 13 and 14 can be surely separated from each other electrically and mechanically.

In this step, since the through electrodes 27 and 28 are exposed to the rear surfaces of the second regions 13 and 14 when the dicing is performed, dicing lines can be set based on the through electrodes 27 and 28 as marks. Therefore, the dicing grooves 30 can be surely provided in the step parts 31. As a result, the dicing grooves 30 enable dicing in portions with which the resin layer 34 is in closest contact. Consequently, a good effect is also brought about for the integral support by the resin layer 34.

In the step described above, as shown in FIG. 9, the first region 12 having the circuit element formed on the substrate 100 is mechanically and electrically separated from the second regions 13 and 14 in which the through electrodes 27 and 28 which are the external connection electrodes, are buried in approximately centers thereof (the region indicated by dashed lines). In this step, the dicing width is set to about 0.1 mm, for example, since it is required to maintain insulating properties between the first region 12 and the second region 13 and 14 after separation thereof. Moreover, as to the dicing depth, as described above, the dicing is performed so as to cut into the resin layer 34 by about 2 μm to 5 μm in order to surely and electrically separate the first region 12 from the second regions 13 and 14. The first region 12 is formed to have a size of 0.5 mm×0.5 mm, and the second regions 13 and 14 are set to have a size of 0.3 mm×0.2 mm.

Finally, a transistor cell X including the first region 12 and the second regions 13 and 14, which are formed on the substrate 100, is separated individually. Thus, a semiconductor device is completed.

In the separation step described above, as shown in FIG. 9, a peripheral portion (shaded area) of the transistor cell X is cut by use of the dicing blade of the dicing apparatus and separated individually. Note that the separation may be performed by etching. However, it is efficient to attach a semiconductor wafer to a dicing sheet and to separate the wafer to form dicing grooves 30 and transistor cells.

According to the embodiment of the present invention, an external connection electrode layer 36 for a collector electrode is provided on the rear surface of the first region 12 of the semiconductor substrate 100. Moreover, an external connection electrode layer 37 for a base electrode and an external connection electrode layer 38 for an emitter electrode are provided on the rear surfaces of the second regions 13 and 14 of the semiconductor substrate 100 (see FIG. 8). The respective external connection electrode layers 36 to 38 are chamfered and etched at the dicing grooves 30 and therearound of the substrate 100 and are formed by plating metal suitable for soldering. Although the respective external connection electrode layers 36 to 38 are arranged in a triangular shape in order to prevent short-circuiting in soldering, the external connection electrodes (external connection electrodes layers) may be linearly arranged. As is clear from FIG. 9, three regions are to be wasted in the triangular shape. Meanwhile, in the linear arrangement, there are no more regions to be wasted.

(Method of Manufacturing Semiconductor Device According to Second Embodiment of the Present Invention)

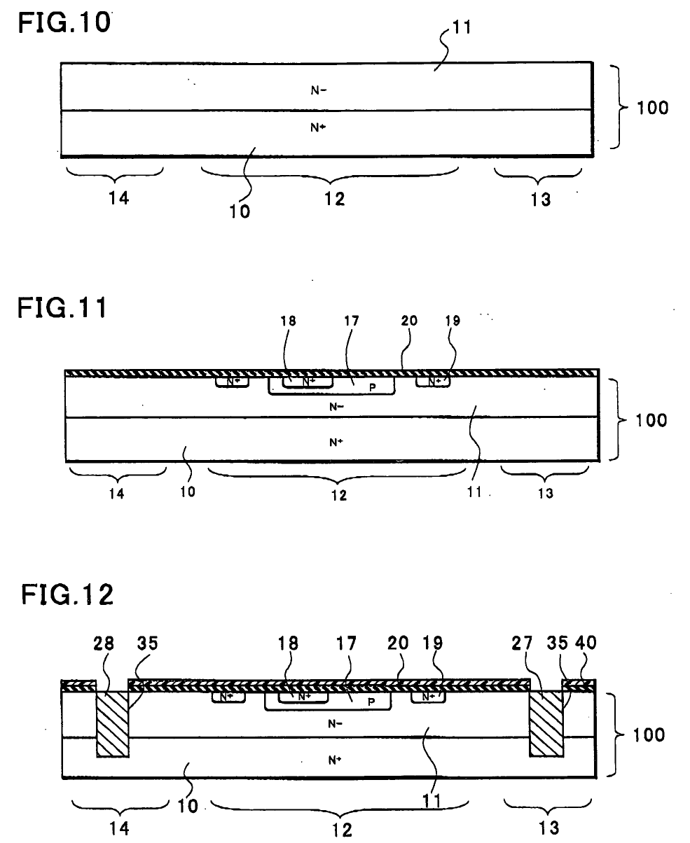

With reference to FIGS. 10 to 16, description will be given of another method for manufacturing a semiconductor device of the embodiment of the present invention.

First, as shown in FIG. 10, an epitaxial layer 11 is formed in an upper surface of a substrate 100 having, on its principal surface, a first region 12 for forming a circuit element and a plurality of second regions 13 and 14 disposed so as to be equally spaced apart from the first region 12 in a periphery of the first region 12.

First, as shown in FIG. 10, on an N+ type semiconductor substrate 10 made of an N+ type single crystal silicon, the N− type epitaxial layer 11 is formed by use of an epitaxial growth technology, thus preparing a substrate 100. The substrate 100 is divided into the first region 12, in which an active circuit element (hereafter circuit element) such as a power MOSFET and a transistor is formed, and the second regions 13 and 14, in which external connection electrodes are formed.

Next, as shown in FIG. 11, the circuit element is formed on the epitaxial layer 11 in the first region 12, and electrodes which are used for connecting the circuit element are formed on a surface of the epitaxial layer 11 in the first region 12.

After an insulating film 20 such as a Si oxide film, which is formed by thermal oxidation or CVD method, is formed on the N− type epitaxial layer 11 on the semiconductor substrate 10, an opening is formed in a part of the insulating film 20 to expose the N− type epitaxial layer 11. After P-type impurities such as boron (B) are selectively implanted into the N− type epitaxial layer 11 in the exposed region, thermal diffusion is performed. Thus, an island-shaped base region 17 is formed on the N− type epitaxial layer 11 in the first region 12.

After the base region 17 is formed, the insulating film 20 is formed again on the first region 12. An opening is formed in the insulating film 20 in a part of the base region 17, and the base region 17 is partially exposed. N type impurities such as phosphorus (P) and antimony (Sb) are selectively implanted into the exposed base region 17. Thereafter thermal diffusion is performed. Thus, an emitter region 18 of a transistor is formed. In this embodiment, simultaneously with formation of the emitter region 18, a ring-shaped N+ type guard ring region 19 which surrounds the base region 17 is formed.

On the surface of the substrate 100, an insulating film 20 such as a silicon oxide film and a silicon nitride film is formed.

Furthermore, as shown in FIG. 12, via holes 35 that reach the semiconductor 10 from the surface are formed in the second regions 13 and 14 of the substrate 100. Moreover, through electrodes 27 and 28 made of metal are formed in the via holes 35.

In this step, the epitaxial layer 11 is dry-etched from its surface by using a resist as a mask. Thus, the via holes 35 are formed, each of which has a width of about 70 μm and a length of about 80 μm. As etching gas used in dry etching, gas containing at least SF₇, O₂ or C₄F₈ is used. The via holes 35 are formed so as to reach the semiconductor substrate 10 from the surface of the epitaxial layer 11. As a specific shape of the via holes 35, a cylindrical shape or a rectangular columnar shape may be used. Furthermore, the via holes 35 can also be formed by wet etching or by using a laser.

Next, the through electrodes 27 and 28 are formed in the via holes 35. The through electrodes 27 and 28 can be formed by plating or sputtering.

In the case where the through electrodes 27 and 28 are formed by plating, first, a seed layer (not shown), which is made of Cu and has a thickness of about several hundred nm, is formed on inner walls of the via holes 35 and on the entire surface of the oxide film 20 on the epitaxial layer 11. Next, electrolytic plating is performed by use of the seed layer as an electrode. Thus, on the inner walls of the via holes 35, the through electrodes 27 and 28 made of Cu are formed.

Although, here, the via holes 35 are completely filled with Cu formed by plating, the filling may be incomplete. Specifically, cavities may be provided in the via holes 35.

Subsequently, electrodes of the circuit element are formed. By removing Cu on the oxide film 20, a base contact hole for exposing a surface of the base region 17 and an emitter contact hole for exposing a surface of the emitter region 18 are formed by etching. In this embodiment, since the guard ring region 19 is formed, a guard ring contact hole for exposing a surface of the guard ring region 19 is simultaneously formed.

Thereafter, on the base region 17, the emitter region 18, the through electrodes 27 and 28 and the guard ring region 19, all of which are exposed by the base contact hole, the emitter contact hole, external connection contact holes and the guard ring contact hole, a metal material such as aluminum is selectively deposited or sputtered. Thus, a base electrode 21, an emitter electrode 22, connection electrodes 25 and 26, and a guard ring 23 are selectively formed. Between the through electrodes 27 and 28 and the connection electrodes 25 and 26, barrier metal which is made of Ti or includes Ti and TiN thereon may be provided.

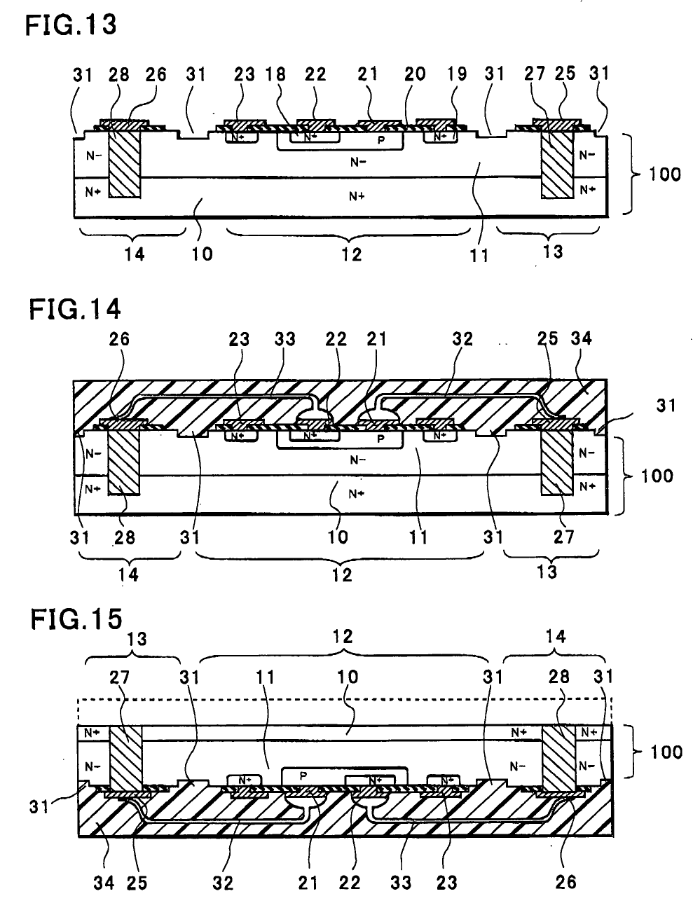

Furthermore, as shown in FIG. 13, step parts 31 are formed by etching at least in regions of the epitaxial layer 11 where dicing grooves are to be formed.

In this step, the step parts 31 are formed by removing the insulating film 20 on the epitaxial layer 11 in regions on boundaries between the first region 12 and the second regions 13 and 14 and by etching the surface of the epitaxial layer 11. In this event, the step parts 31 may be simultaneously formed in the epitaxial layer 11 in the outside portions of the second regions 13 and 14. By forming the step parts 31, the periphery of the first region 12 and the peripheries of the second regions 13 and 14 are exposed from the insulating film 20. Furthermore, the step parts 31, the surface of the epitaxial layer 11, the oxide film 20 and the respective electrodes of the circuit element, the connection electrodes 25 and 26 form stair-like steps. Accordingly, an area of adhesion to a resin layer can be increased. Thus, the area of adhesion to the resin layer can be extended.

Furthermore, as shown in FIG. 14, on the principal surface of the substrate 100, connection electrically connecting the electrodes of the circuit element to the external connection electrodes is formed. Thereafter, a resin layer 34, which integrally supports the first region 12 and the second regions 13 and 14, is formed on the surface of the epitaxial layer 11. Thus, the resin layer 34 adheres to the step parts 31.

The connection electrodes 25 and 26 corresponding to the base electrode 21 and the emitter electrode 22 are connected thereto by bonding with thin metal wires 32 and 33. Note that, instead of the thin metal wires 32 and 33, it is also possible to use a wiring substrate obtained by forming wiring in a substrate such as a glass epoxy substrate, a ceramic substrate, an insulated metal substrate, a phenol substrate and a silicon substrate.

The resin layer 34 is formed so as to insulate the connection 32 and 33 connecting the base electrode 17 and the emitter electrode 18 of the transistor to the connection electrodes 25 and 26 as described above from the substrate 100. Moreover, the resin layer 34 is formed so as to integrally support the first region 12 and the second regions 13 and 14 when the first region 12 is mechanically separated from the second regions 13 and 14. As the resin layer 34, one including adhesive properties and insulating properties may be used, and, for example, a polyimide resin is preferable.

On the surface of the substrate 100, a polyimide resin having a thickness of 2 μm to 50 μm is applied by use of a spinner, for example. After burning for a predetermined period of time, the resin layer 34 having its surface polished and flattened is formed. Here, regarding the connection of the thin metal wires, the wafer can be used in its thick state unlike the first embodiment. Thus, the wafer itself has a strength and it is possible to suppress cracks and the like in the wafer due to an external force caused by bonding or the like.

Furthermore, as shown in FIG. 15, a thickness of the semiconductor substrate 10 is reduced by grinding the substrate 10 from its rear surface. Thus, the through electrodes 27 and 28 are exposed from the rear surfaces of the second regions 13 and 14.

The surface of the substrate 100 is attached to a wafer support by use of wax and the like, and the semiconductor substrate 10 is back-grind from its rear surface to remove an unnecessary portion thereof. Accordingly, the thickness of the semiconductor substrate 10 is reduced to about 400 μm to about 100 μm. In this event, since the through electrodes 27 and 28 are exposed from the rear surface of the semiconductor substrate 10, the through electrodes 27 and 28 are set as a base of positioning in dicing groove formation in a subsequent step. Moreover, since the through electrodes 27 and 28 reach the rear surface of the semiconductor substrate 10 from the surface of the epitaxial layer 11, a leading-out resistance of the electrodes can be significantly reduced. Although, here, back grinding is performed, some etching may be subsequently performed to remove distortions or scratches. Moreover, CMP can also be adopted. Furthermore, plasma etching or wet etching may be adopted.

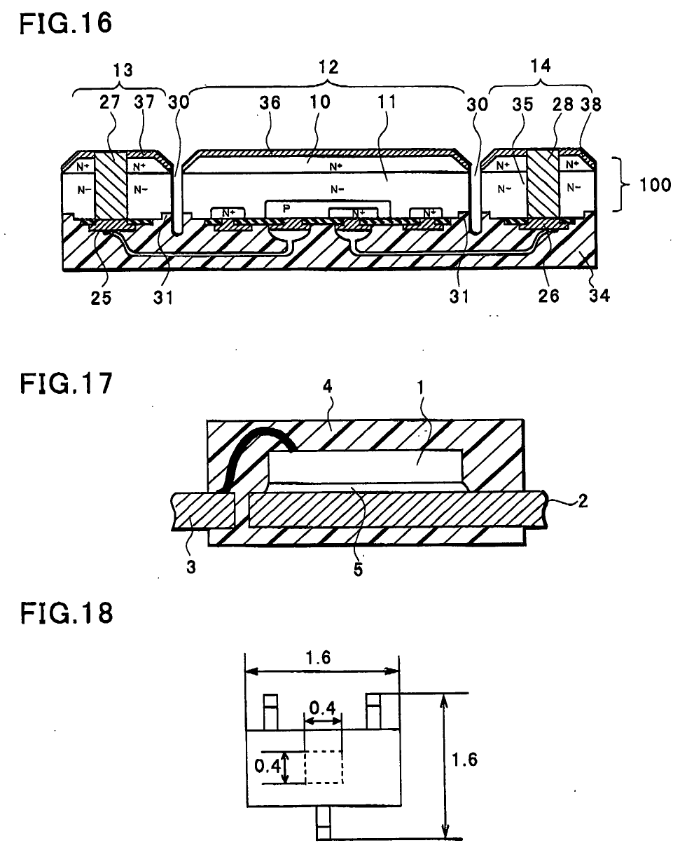

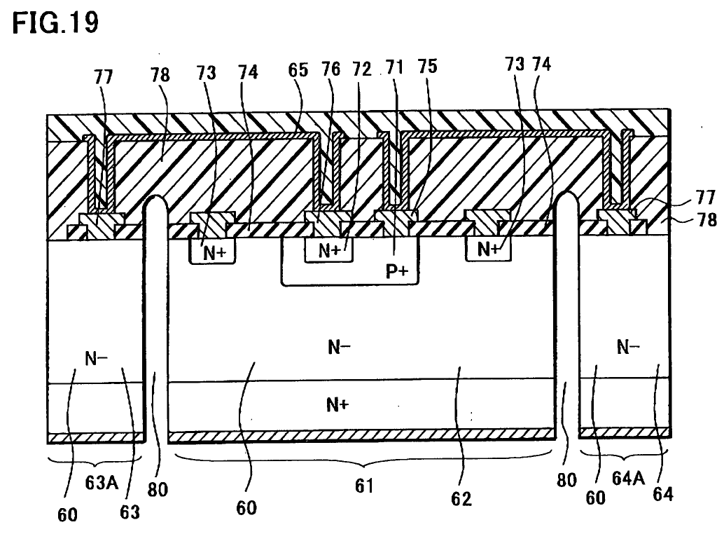

Furthermore, as shown in FIG. 16, based on the through electrodes 27 and 28, dicing grooves 30 that reach the resin layer 34 are formed in the semiconductor substrate 10 and the epitaxial layer 11 on boundaries between the first region 12 and the second regions 13 and 14 from the rear surface of the semiconductor substrate 10. Accordingly, the substrate 100 in the first region 12 and the substrate 100 in the second regions 13 and 14 are electrically separated from each other. Thus, external connection electrodes made of the substrate 10 in the second regions 13 and 14 are formed.

The dicing grooves 30 are formed so as to reach the resin layer 34 from the rear surface of the semiconductor substrate 10, and are formed by use of a mechanical method using a dicing apparatus.

The reason why the dicing grooves 30 are formed by use of the dicing apparatus is because dicing width and depth can be accurately controlled and the dicing apparatus is an existing equipment so that it is not required to purchase a new equipment. The dicing width is set according to a width of a dicing blade, and the dicing depth varies depending on dicing apparatus manufacturers. In the current technology, an error in accuracy of the dicing depth is about 2 μm to 5 μm. Thus, without cutting the connection 32 and 33, the first region 12 and the second regions 13 and 14 can be surely separated from each other electrically and mechanically.

In this step, since the through electrodes 27 and 28 are exposed to the rear surfaces of the second regions 13 and 14 when the dicing is performed, dicing lines can be set based on the through electrodes 27 and 28 as marks. Therefore, the dicing grooves 30 can be surely provided in the step parts 31. As a result, the dicing grooves 30 enable dicing in portions with which the resin layer 34 is in closest contact. Consequently, a good effect is also brought about for the integral support by the resin layer 34.

In the step described above, as shown in FIG. 9, the first region 12 having the circuit element formed on the substrate 100 is mechanically and electrically separated from the second regions 13 and 14 in which the through electrodes 27 and 28 which are the external connection electrodes, are buried in approximately centers thereof (the region indicated by dashed lines). In this step, the dicing width is set to about 0.1 mm, for example, since it is required to maintain insulating properties between the first region 12 and the second regions 13 and 14 after separation thereof. Moreover, as to the dicing depth, as described above, the dicing is performed so as to cut in the resin layer 34 by about 2 μm to 5 μm in order to surely and electrically separate the first region 12 from the second regions 13 and 14. The first region 12 is formed to have a size of 0.5 mm×0.5 mm, and the second regions 13 and 14 are set to have a size of 0.3 mm×0.2 mm.

Finally, a transistor cell X including the first region 12 and the second regions 13 and 14, which are formed on the substrate 100, is separated individually. Thus, a semiconductor device is completed.

In the separation step described above, as shown in FIG. 9, a peripheral portion (shaded area) of the transistor cell X is cut by use of the dicing blade of the dicing apparatus and separated individually. Note that the separation may be performed by etching. However, it is efficient to attach a semiconductor wafer to a dicing sheet and to separate the wafer to form dicing grooves 30 and transistor cells.

According to the embodiment of the present invention, an external connection electrode layer 36 for a collector electrode is provided on the rear surface of the first region 12 of the semiconductor substrate 100. Moreover, an external connection electrode layer 37 for a base electrode and an external connection electrode layer 38 for an emitter electrode are provided on the rear surfaces of the second regions 13 and 14 of the semiconductor substrate 100 (see FIG. 16). The respective external connection electrode layers 36 to 38 are chamfered and etched at the dicing grooves 30 and therearound of the substrate 100 and are formed by plating metal suitable for soldering. Although the respective external connection electrode layers 36 to 38 are arranged in a triangular shape in order to prevent short-circuiting in soldering, the external connection electrodes may be linearly arranged.

According to the semiconductor device of the embodiment of the present invention, the step parts are provided in the first and second regions of the substrate 100, which are adjacent to the dicing grooves. Accordingly, surfaces of the first and second regions of the substrate 100 are exposed and come into contact with the resin layer. Thus, adhesion strength of the resin layer is enhanced and adhesion is improved.

Moreover, in the step parts, stair-like steps are formed in both of the first and second regions of the substrate 100. Moreover, the resin layer is formed to have the largest thickness in the regions of the dicing grooves. Thus, an area of adhesion of the resin layer to the substrate 100 in the peripheries of the first and second regions of the substrate 100 can be increased. The strength of the resin layer itself can also be increased most. In addition, in the step parts, some distance from the dicing grooves to the circuit element or the through electrodes can be gained. Thus, moisture-absorption characteristics can also be improved.

Furthermore, by forming the through electrodes by use of metal, a connection resistance value is lowered.

In the method of manufacturing a semiconductor device of the embodiments of the present invention, the via holes can be formed from the rear surface of the semiconductor substrate 10. Accordingly, the through electrodes formed in the via holes can be exposed to the rear surface of the semiconductor substrate 10 (the substrate 100). Thus, the first and second regions of the substrate 100, which are separated by the dicing grooves, can be recognized based on the through electrodes. Consequently, positioning can be facilitated.

Moreover, as a result, the dicing grooves are surely formed in the step parts where the resin layer has strong adhesion and strength. Thus, the first and second regions can be supported and fixed on the same plane.

What is claimed is:

1. A semiconductor device comprising:
a substrate having a first and a second region;
a circuit element provided in the first region and a plurality of electrodes connected to the circuit element;
an external connection electrode having a metallic through electrode buried in the second region;
a dicing groove which divides the substrate into the first region and the second region;
connections electrically connecting the electrodes to the external connection electrode;
step parts which are provided on surfaces of the first and second regions of the substrate adjacent to the dicing groove, and expose a part of the substrate; and
a resin layer which is provided on the surface of the substrate including the step parts so as to support integrally the first and second regions of the substrate.

2. The semiconductor device according to claim 1, wherein the through electrode reaches a rear surface of the second region.

3. The semiconductor device according to claim 1, wherein the resin layer is formed of a polyimide resin, and a stair-like shape is formed from the step parts to the electrodes or the external connection electrode to improve adhesion of the polyimide resin.

4. A method of manufacturing a semiconductor device, comprising the steps of:
forming an epitaxial layer in an upper surface of a substrate having, on its principal surface, a first region for forming a circuit element and a plurality of second regions disposed so as to be equally spaced apart from the first region in a periphery of the first region;
forming the circuit element on the epitaxial layer in the first region;
forming step parts at least in regions where dicing grooves are to be formed in the epitaxial layer;
reducing a thickness of the substrate from a rear surface thereof, forming via holes that reach a surface of the substrate from the rear surface thereof in the second regions, and forming through electrodes made of metal in the via holes;
forming connection electrically connecting electrodes of the circuit element to the through electrodes on the principal surface of the substrate;
improving adhesion to the step parts by forming a resin layer which integrally supports the first region and the second regions on a surface of the epitaxial layer; and
forming the dicing grooves that reach the resin layer in the substrate on boundaries between the first region and the second regions based on the through electrodes from the rear surface of the substrate, electrically separating the substrate in the first region from the substrate in the second regions, and forming external connection electrodes made of the substrate in the second regions.

5. The method of manufacturing a semiconductor device, according to claim 4, wherein the through electrodes are formed by plating copper in the via holes.

6. The method of manufacturing a semiconductor device, according to claim 4, wherein the step parts are formed so as to surround the first and second regions of the substrate, respectively.

7. A method for manufacturing a semiconductor device, comprising the steps of:
preparing a substrate having, on its principal surface, a first region for forming a circuit element and a plurality of second regions disposed so as to be equally spaced apart from the first region in a periphery of the first region by providing an epitaxial layer on a semiconductor substrate;
forming the circuit element on the epitaxial layer in the first region;
forming via holes that reach the semiconductor substrate from surfaces in the second regions of the substrate, and forming through electrodes made of metal in the via holes;
forming step parts at least in regions where dicing grooves are to be formed in the epitaxial layer;
forming connection electrically connecting electrodes of the circuit element to the through electrodes on a surface of the epitaxial layer;
improving adhesion to the step parts by forming a resin layer which integrally supports the first region and the second regions on the surface of the epitaxial layer;
reducing a thickness of the semiconductor substrate by grinding the semiconductor substrate from its rear surface, and exposing the through electrodes from rear surfaces of the second regions; and
forming the dicing grooves that reach the resin layer in the substrate on boundaries between the first region and the second regions based on the through electrodes from a rear surface of the substrate, electrically separating the substrate in the first region from the substrate in the second regions, and forming external connection electrodes made of the substrate in the second regions.

8. The method of manufacturing a semiconductor device, according to claim 7, wherein the through electrodes are formed by plating copper in the via holes.

9. The method of manufacturing a semiconductor device, according to claim 7, wherein the step parts are formed so as to surround the first and second regions of the substrate, respectively.
